(19) United States
(12) Patent Application Publication
(10) Pub. No.: US 2026/0239975 A1
(43) Pub. Date: Aug. 13, 2026

(54) POWER INVERTER ASSEMBLY WITH BYPASS WALL FOR DIVERTING FLUID

(71) Applicant: DENSO International America, Inc., Southfield, MI (US)

(72) Inventors: Siddharth DASGUPTA, Windsor (CA); Sergio PUJOLS, Canton, MI (US)

(21) Appl. No.: 19/051,581

(22) Filed: Feb. 12, 2025

(51) Int. Cl. H01L 23/46; H01L 25/07; H05K 7/20

(52) U.S. Cl. CPC H10W 40/40; H05K 7/20927; H10W 90/00

(57) ABSTRACT

A power inverter assembly has a heat sink with a bypass wall for diverting fluid. The power assembly has a first power card with a first group of chips, and a second power card with a second group of chips. The heat sink has an inlet region, and outlet region, and a base that contacts the first and second power cards. The heat sink has fins spanning from the inlet region to the outlet region and extending from the upper surface to draw heat from the first and second power cards. The fins include a first group of fins generally aligned with the first group of chips, and a second group of fins generally aligned with the second group of chips. The bypass wall diverts fluid from the inlet region to the second group of fins while bypassing at least a portion of the first group of fins.

### TECHNICAL FIELD

The present disclosure relates to a power inverter assembly with a bypass wall (e.g., in a heat sink) for diverting fluid.

### BACKGROUND

The performance, lifespan, and safety of many electrical components are dependent on the temperature at which the electrical components operate and a build-up of heat can negatively affect these elements. The temperature of the electrical component may be affected by heat generated from the electrical component or its surrounding environment. Heat sinks are used to dissipate heat from electrical components or other heat-generating devices and prevent the negative effects from a build-up of heat. Some heat sinks use pin fins that extend outward from a base that is in thermal communication with the electrical component. As fluids (e.g., air, water, or the like) flow along the heat sink in between the pin fins, the pin fins transfer the heat from the electrical component to the fluid, cooling the electrical component.

### SUMMARY

In an embodiment, a power inverter assembly for a motor vehicle comprises a first power card having a first group of chips, a second power card having a second group of chips, and a heat sink. The heat sink includes an inlet region, an outlet region, and a base having a lower surface and an opposing upper surface, wherein the lower surface contacts the first and second power cards. The heat sink includes a plurality of fins spanning from the inlet region to the outlet region and extending from the upper surface to draw heat from the first and second power cards, wherein the plurality of fins includes a first group of fins generally aligned with the first group of chips, and a second group of fins generally aligned with the second group of chips. The heat sink includes a bypass wall that diverts fluid from the inlet region to the second group of fins while bypassing the first group of fins.

In an embodiment, a heat sink for cooling power cards comprises an inlet region, an outlet region, and a base having a lower surface and an opposing upper surface, wherein the lower surface contacts the first and second power cards. The heat sink further comprises a plurality of fins spanning from the inlet region to the outlet region and extending from the upper surface for drawing heat from power cards located beneath the heat sink, wherein the plurality of fins includes a first group of fins located near the inlet region and a second group of fins located near the outlet region. The heat sink further comprises a bypass wall extending from the upper surface of the base and in a gap between some of the plurality of fins, the bypass wall and configured to divert fluid from the inlet region to the second group of fins while bypassing at least some of the first group of fins.

In an embodiment, a heat sink for cooling power cards comprises an inlet region, an outlet region, and a base having a lower surface and an opposing upper surface, wherein the lower surface contacts the first and second power cards. The heat sink further comprises a plurality of fins spanning from the inlet region to the outlet region and extending from the upper surface for drawing heat from power cards located beneath the heat sink, wherein the plurality of fins includes a first group of fins located near the inlet region and a second group of fins located near the outlet region, and wherein each of the plurality of fins includes a lower end at the upper surface of the base and an opposing upper end spaced from the base. The heat sink further comprises a bypass wall vertically spaced from the upper surface of the base and configured to divert fluid from the inlet region to the second group of fins while bypassing at least some of the first group of fins, wherein the bypass wall extends along the upper ends of at least some of the first group of fins.

### BRIEF DESCRIPTION OF THE DRAWINGS

FIG. 1A is a perspective view of a heat sink, according to an embodiment.

FIG. 1B is a perspective view of an opposite side of the heat sink of FIG. 1A, according to an embodiment.

FIG. 2 is a top view of a heat sink having a bypass wall according to a first embodiment.

FIG. 3A is a perspective view of a heat sink having a bypass wall according to a second embodiment.

FIG. 3B is a cross-sectional view of the heat sink of FIG. 3A taken along line 3B-3B of FIG. 3A.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative bases for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical application. Various combinations and modifications of the features consistent with the teachings of this disclosure, however, could be desired for particular applications or implementations.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions.

An inverter card is an electronic component used to convert direct current (DC) to alternating current (AC), typically in applications such as powering AC motors, lighting, and other devices from a DC source. Inverters are common in power electronics and are widely used in renewable energy systems (like solar power), electric vehicles, and uninterruptible power supplies (UPS). Inverter cards can include several components, such as power transistors, driver circuits, capacitors, inductors. Inverter cards can also include chips, e.g., integrated circuits (ICs) that perform various control, processing, and support functions.

Since the power transistors and other components on an inverter card generate significant heat during operation, heat sinks are typically relied upon for drawing heat away from the inverter cards and preventing overheating. Heat sinks are typically made from thermally conductive materials, such as aluminum or copper, which transfer heat efficiently. The heat generated by the transistors and other components flows into the heat sink through direct contact or through a thermally conductive pad or paste. From there, the heat is dissipated into the surrounding air or fluid (gas or liquid). This process keeps the inverter card at a safe operating temperature, which protects components from thermal damage and prolongs their lifespan.

One common problem with heat sinks, particularly in liquid-cooled systems, is uneven cooling distribution due to temperature gradients in the coolant as it flows from the inlet to the outlet. When the coolant first enters the heat sink, it is at its lowest temperature, allowing for efficient heat transfer from the components to the coolant. However, as the coolant absorbs heat along its path, it gradually warms up, decreasing its ability to absorb additional heat near the outlet. This results in uneven cooling efficiency, where components near the coolant inlet receive the most effective cooling, while those closer to the outlet experience reduced cooling efficiency. This temperature gradient can lead to localized hot spots, making it challenging to maintain consistent cooling performance across all components. Optimizing coolant flow and temperature regulation is essential in managing this phenomenon, especially in high-power applications where thermal balance is critical.

Therefore, according to embodiments disclosed herein, an inverter assembly is provided with a heat sink having a bypass wall that diverts some of the fluid from the inlet to a different region of the heat sink. The bypass wall allows “fresh” fluid from the inlet (or at least fluid that has not been significantly warmed yet) to be applied directly to an area of the heat sink that is located more toward the outlet. This allows chips and other components in the power cards located near the outlet of the inverter assembly to be cooled more effectively and efficiently in that the region of the heat sink that is aligned with these power cards is receiving fresh fluid from the inlet that has not yet experienced significant heat transfer.

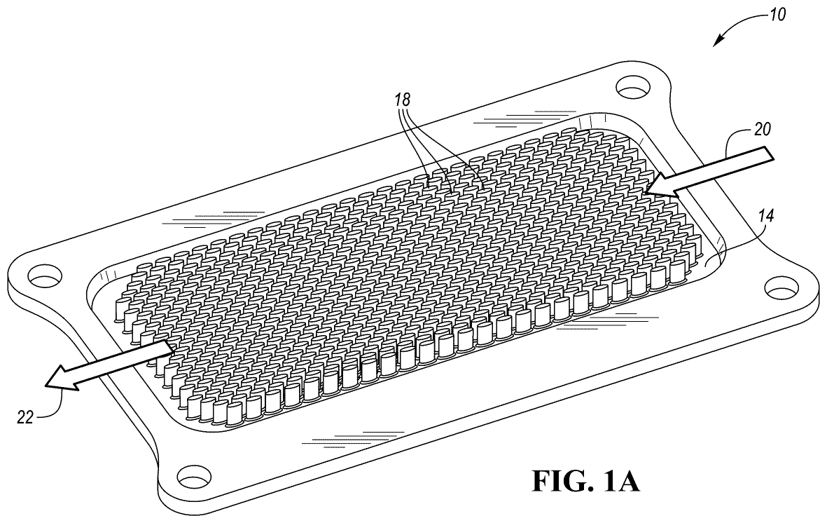

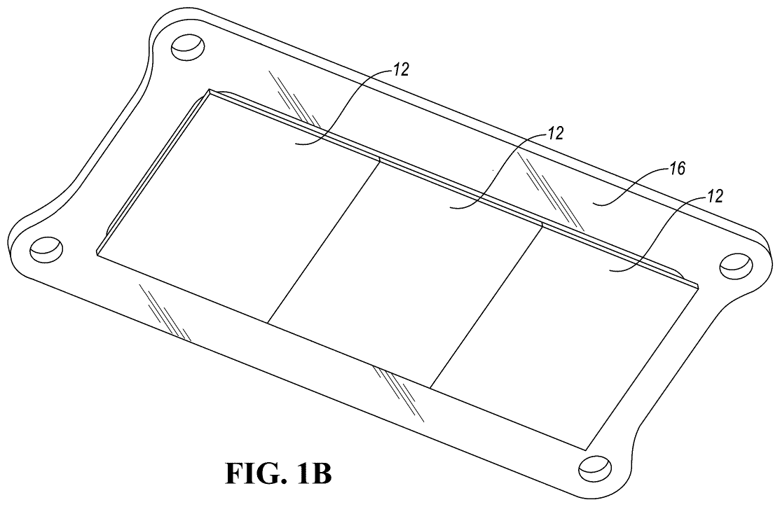

As shown in FIGS. 1A-1B, according to the prior art, a heat sink 10 is shown for dissipating heat from a device capable of generating heat, such an electrical or computer component, an inverter card, or the like. Here, three separate power cards 12 are shown. It should be understood that “power cards” can generally refer to any circuit board that manages or processes power within a system, and that may handle various power-related tasks such as voltage conversion, regulation, distribution, and protection, and DC-to-AC conversion (i.e., inverter card). The power cards 12 may also not necessarily be designed for DC-to-AC conversion, but instead may handle AC-DC conversion, DC-DC conversion, or simply regulate power for different parts of a system. In general, an inverter card can be considered a type of power card due to its power-handling role, but the power card is a broader term intended to refer to any circuit board that manages or processes power and generates heat as a result.

As shown, the heat sink 10 has an upper surface 14 and an opposing lower surface 16. The power card(s) 12 are in direct contact with the lower surface 16. The heat sink 10 also has plurality of fins 18 (e.g., pins, projections, protrusions, or the like) configured to increase the surface area of the heat sink for more effective heat transfer.

Assume an inlet is generally aligned with the right-hand side of the heat sink (as shown by arrow 20) so that an inlet of fluid (e.g., air, liquid, etc.) engages with the fins on the right-hand side of the heat sink, and the fluid travels from right-to-left across the heat sink and between the fins 18, whereupon the fluid exits an outlet of the heat sink (as shown by arrow 22) near the left-hand side of the heat sink 10. As explained above, the fluid becomes warmer as the fluid travels from right to left across the heat sink 10. This means that less effective heat transfer takes place on the left-hand side of the heat sink, which can lead to the correspondingly aligned power cards on the left-hand side being subject to less effective heat transfer. In other words, the power cards on the left (closer to the outlet) of the heat sink might not be cooled as effectively as the power cards on the right (closer to the inlet) of the heat sink.

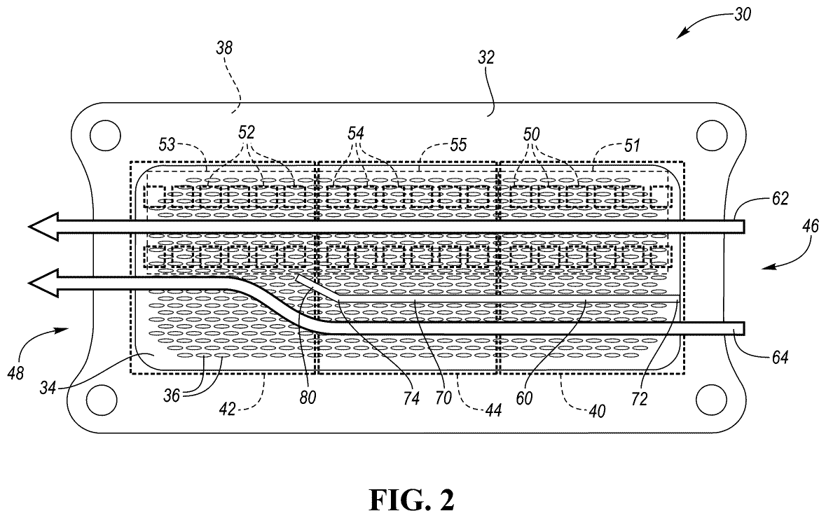

FIG. 2 illustrates a power inverter assembly 30 according to a first embodiment. The power inverter assembly 30 includes a heat sink 32, the top side of which is shown in FIG. 2. Here, like in FIG. 1, the heat sink 32 includes an upper surface 34 having a plurality of fins 36 for heat transfer. The heat sink 32 also includes an opposing lower surface 38 for making direct contact with a plurality of power cards, namely a first power card 40, a second power card 42, and a third power card 44. In the illustrated embodiment, the first power card 40 is located near or adjacent an inlet region 46 of the heat sink 32, and the second power card 42 is located near or adjacent an outlet region 48 of the heat sink 32. In this fashion, fluid that comes in contact with the upper surface 34 of the heat sink 32 near the inlet region 46 will work to cool a region of heat sink 32 aligned with the first power card 40 on the bottom of the heat sink 32, and the fluid that contacts the upper surface 34 of the heat sink near the outlet region 48 will work to cool a region of the heat sink 32 aligned with the second power card 42 on the bottom of the heat sink 32. The third power card 44 is located between the first power card 40 and the second power card 42. Of course, more or less power cards can be provided, and the exact number and arrangement of power cards shown herein is only an example.

Each power card has a group of chips. For example, the first power card 40 has a first group of chips 50, the second power card 42 has a second group of chips 52, and the third power card 44 has a third group of chips 54. The various chips can include microcontrollers or Digital Signal Processors (DSPs), driver ICs, voltage regulators, logic and control ICs, protection ICs, communication ICs, or the like. The chips may be heat-producing objects, and if not properly cooled, excess heat can cause damage and potential system failure, including thermal degradation, electrical overstress, solder joint failures, performance degradation, and the like.

As explained above, the fins 36 help to efficiently transfer heat from the heat sink 32. The fins 36 can be spread all across a majority of the upper surface 34 on an opposite side of the heat sink 32 from the chips so as to include a first group of fins 51 generally aligned with the first group of chips 50, a second group of fins 53 generally aligned with the second group of chips 52, and a third group of fins 55 generally aligned with the third group of chips 54.

If fluid were allowed to travel from the inlet 46 to the outlet 48 with no specific direction, the second group of fins 53 (and thereby the second group of chips 52) might be subject to less efficient heat transfer due to the fluid increasing in temperature as it travels from inlet 46 to outlet 48 (e.g., right to left in FIG. 2). As the fluid travels over the heat sink 32, it first cools the heat sink in the area aligned with the first power card 40, then it cools the heat sink in the area aligned with the third power card 44, and then it finally cools the heat sink in the area aligned with the second power card 42. This can cause inefficient heat transfer, particularly in the area of the heat sink 32 aligned with the second power card 42.

Therefore, according to an embodiment, the heat sink 32 is provided with a bypass wall 60. The bypass wall 60 can extend from the upper surface 34 of the heat sink 32. The bypass wall 60 can also extend between some of the fins 36, e.g. within gaps existing between adjacent fins. Alternatively, especially if the heat sink 32 is made from additive manufacturing (e.g., 3D printing), the bypass wall 60 can intersect and be unitarily or integrally formed with some of the fins 36.

The bypass wall 60 is configured to divert fluid that enters the inlet 46 to bypass the regions of the heat sink aligned with the first group of chips 50 and the third group of chips 54, and travel directly to the region of the heat sink 32 aligned with the second group of chips 52. Said another way, the bypass wall 60 is configured to divert fluid from the inlet region 46 to the second group of fins 53 while bypassing the first group of fins 51 (and the third group of fins 55).

The bypass wall 60 segregates the fluid so as to provide two fluid flow paths, including a first fluid flow path 62 and a second fluid flow path 64. In the first fluid flow path 62, the fluid travels from the inlet 46, then across the first group of fins 51, then across the third group of fins 55, and then across the second group of fins 53, and to the outlet 48. In the second fluid flow path 64, the fluid travels from the inlet 46, then bypasses the first group of fins 51 and the third group of fins 55, and then is directed toward the second group of fins 53 before exiting the outlet 48. This allows fresh, cool fluid that has been subjected to a reduced amount of heat transfer (compared to the first fluid flow path) to work to cool the second group of chips 52 via the aligned second group of fins 53.

The bypass wall 60 can include two connected wall segments, namely a first wall 70 and a second wall 80. The first wall 70 has a first end 72 located toward or at the inlet 46, and a second end 74 opposite the first end 72 that terminates at a location downstream of the first end 72 (i.e., more toward the outlet 48 than the first end 72 is). The second end 74 is also where the second wall 80 begins. In particular, the second wall 80 can extend from the second end 74 at an oblique angle, as shown in FIG. 2. The angle of the second wall 80 is such that it allows fluid to flow over some of the second group of fins 53 that are aligned with the second group of chips 52. This allows the second fluid flow path 64 to take its shape, allowing relatively fresh fluid to cool the second group of chips 52. The second wall 80 can begin at a location upstream of the second group of fins 53 (e.g., where the first wall 70 terminates), and terminate within the second group of fins 53. Further, the second wall 80 can terminate at a location substantially upstream of a majority of the second group of chips 52.

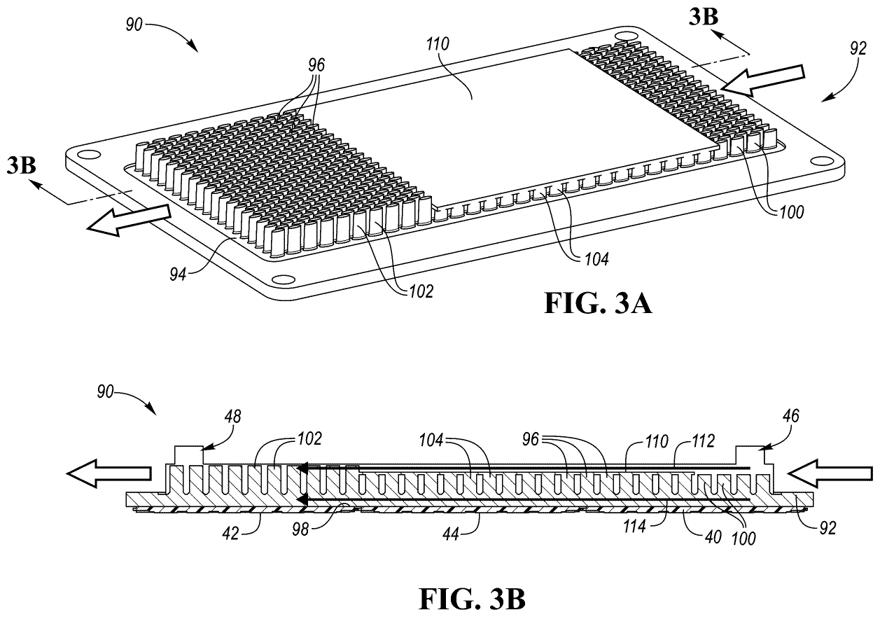

FIGS. 3A-3B illustrates a power inverter assembly 90 according to a second embodiment; FIG. 3A shows the power inverter assembly 90 in perspective, and FIG. 3B shows the power inverter assembly 90 in a cross-sectional view taken along line 3B-3B in FIG. 3A. It should be understood that the second embodiment can incorporate all of the features of the first embodiment (and vice versa) unless the description and context described herein dictates otherwise.

The power inverter assembly 90 includes a heat sink 92. The heat sink 92 includes an upper surface 94 having a plurality of fins 96 for heat transfer. Similar to the first embodiment, the heat sink 92 also includes an opposing lower surface 98 for making direct contact with a plurality of power cards, namely first power card 40, second power card 42, and third power card 44. Also similar to the first embodiment, the first power card 40 is located near or adjacent an inlet region 46 of the heat sink 92, and the second power card 42 is located near or adjacent an outlet region 48 of the heat sink 92. In this fashion, fluid that comes in contact with the upper surface 94 of the heat sink 92 near the inlet region 46 will work to cool a region of heat sink 92 aligned with the first power card 40 on the bottom of the heat sink 92, and the fluid that contacts the upper surface 94 of the heat sink near the outlet region 48 will work to cool a region of the heat sink 92 aligned with the second power card 42 on the bottom of the heat sink 92.

As explained above, the fins 96 help to efficiently transfer heat from the heat sink 92. The fins 96 can be spread all across a majority of the upper surface 94 on an opposite side of the heat sink 92 from the chips. In this embodiment, the plurality of fins 96 includes a first group of fins 100 and a second group of fins 102, with at least some of the first group of fins 100 generally aligned with the first group of chips 50 of the first power card 40, and at least some of the second group of fins 102 generally aligned with the second group of chips 52 of the second power card 42. Also, some of the first group of fins 102 can be aligned with the third group of chips 54 of the third power card 44.

As shown in the illustrated embodiment, the first group of fins 100 is shorter than the second group of fins 102, with at least some of the first group of fins 100 terminating at a bypass wall 110. In embodiments, the top surfaces of at least some of the first group of fins 100 are integrally connected by the bypass wall 110. For example, additive manufacturing (e.g., 3D printing) can be implemented such that the bypass wall 110 is part of a single, monolithic material with at least some of the first group of fins 100. In other embodiments, the bypass wall 110 is a separate component that is attached (e.g., adhered, welded, etc.) to the top surfaces of the first group of fins 100. In either embodiment, it can be said that the bypass wall 110 is a plate that extends horizontally in order to vertically separate two fluid flow paths.

The bypass wall 110 allows the incoming fluid to flow in two general paths: a first fluid flow path 112 that is above the bypass wall 110, and a second fluid flow path 114 that is below the bypass wall 110. This allows at least some of the incoming fluid to flow directly to the second group of fins 102 that are aligned with the second power card 42 while bypassing the fins beneath the bypass wall 110. This provides the second group of fins 102 with fresh fluid from the first flow path 112 that has been subjected to a reduced amount of heat transfer compared to the second fluid flow path 114, allowing for a more efficient heat transfer to take place in the second group of fins 102.

The bypass wall 110 can be generally parallel to the upper surface 94 of the base of the heat sink 92. The bypass wall can be generally rectangular, with a length extending parallel to the general direction of the fluid flow from the inlet to the outlet. Moreover, the bypass wall 110 can be located vertically closer to an upper surface of the second group of fins 102 than the upper surface 94. In other words, a distance between the upper surface 94 of the heat sink 92 and the lower surface of bypass wall 110 is greater than a distance between the upper surface of the bypass wall 110 and a plane that interconnects the upper surfaces of the second group of fins 102. This allows for a majority of the incoming fluid from the inlet region 46 to flow into the second fluid flow path 114, and a minority of the incoming fluid from the inlet region 46 to flow into the first fluid flow path 112. Thus, a majority of the fresh inlet fluid works to cool the first group of fins 100, but a sufficient amount of the fresh inlet fluid is allows to travel above the bypass wall 110 and to the second group of fins 102.

The plurality of fins 96 can, of course, include a third group of fins 104 that is generally aligned with the third power card 44. In embodiments, the bypass wall 110 can extend over all of the fins of the third group of fins 104. This allows the fluid in the first fluid path 112 to completely bypass the third group of fins 104, and instead proceed directly to the second group of fins 102. Thus, the fluid in the first fluid path 112 will not make direct contact with the third group of fins 104, allowing for less heat transfer to take place in this region due to the reduced amount of surface area making contact with the fluid in the first fluid path 112.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A power inverter assembly for a motor vehicle, the power inverter assembly comprising:
a first power card having a first group of chips;
a second power card having a second group of chips; and
a heat sink comprising:
an inlet region;
an outlet region;
a base having a lower surface and an opposing upper surface, wherein the lower surface contacts the first and second power cards;
a plurality of fins spanning from the inlet region to the outlet region and extending from the upper surface to draw heat from the first and second power cards, wherein the plurality of fins includes a first group of fins generally aligned with the first group of chips, and a second group of fins generally aligned with the second group of chips; and
a bypass wall that diverts fluid from the inlet region to the second group of fins while at least partially bypassing the first group of fins.

2. The power inverter assembly of claim 1, wherein the bypass wall extends from the upper surface of the base.

3. The power inverter assembly of claim 2, wherein the bypass wall includes:
a first wall segment having a first end in the inlet region and a second end terminating at a location upstream of the second group of fins; and
a second wall segment angled obliquely relative to the first wall segment and extending from the second end to the second group of fins.

4. The power inverter assembly of claim 3, further comprising a third power card having a third group of chips, wherein the third power card is located between the first and second power cards,
wherein the plurality of fins includes a third group of fins generally aligned with the third group of chips,
wherein the first wall segment of the bypass wall extends through fins that are generally aligned with the first power card but not generally aligned with the first group of chips, and
wherein the second wall segment of the bypass wall extends through fins that are generally aligned with the third power card but not generally aligned with the third group of chips.

5. The power inverter assembly of claim 1, wherein each of the plurality of fins includes a lower end at the upper surface of the base and an upper end spaced from the base;
wherein the bypass wall is spaced from the upper surface of the base and extends along the upper ends of at least some of the first group of fins.

6. The power inverter assembly of claim 5, wherein the bypass wall is a plate formed integrally with the upper ends of the first group of fins.

7. The power inverter assembly of claim 5, wherein the fins within the first group of fins are shorter than the fins within the second group of fins.

8. The power inverter assembly of claim 7, wherein the bypass wall is parallel or angled or curved to the upper surface of the base, and wherein a distance between the upper surface of the base and the bypass wall is less than a distance between the upper surface of the base and the upper ends of the fins within the second group of fins.

9. The power inverter assembly of claim 8, wherein the bypass wall terminates upstream of the second group of fins.

10. The power inverter assembly of claim 7, wherein the bypass wall has an upper surface and a lower surface, and wherein a distance between the upper surface of the base and the lower surface of bypass wall is greater than a distance between the upper surface of the bypass wall and an upper surface of the second group of fins.

11. The power inverter assembly of claim 5, further comprising a third power card having a third group of chips, wherein the third power card is located between the first and second power cards,
wherein the plurality of fins includes a third group of fins generally aligned with the third group of chips, and
wherein the bypass wall extends over at least some of the fins of the first group of fins, and over at least some of the fins of the third group of fins.

12. A heat sink for cooling power cards, the heat sink comprising:
an inlet region;
an outlet region;
a base having a lower surface and an opposing upper surface;
a plurality of fins spanning from the inlet region to the outlet region and extending from the upper surface for drawing heat from power cards contacting the lower surface, wherein the plurality of fins includes a first group of fins located near the inlet region and a second group of fins located near the outlet region; and
a bypass wall extending from the upper surface of the base, the bypass wall and configured to divert fluid from the inlet region to the second group of fins while bypassing at least some of the first group of fins.

13. The heat sink of claim 12, wherein the bypass wall includes:
a first wall segment having a first end in the inlet region and a second end terminating at a location upstream of the second group of fins; and
a second wall segment angled obliquely relative to the first wall segment and extending from the second end to the second group of fins.

14. The heat sink of claim 13, wherein the first group of fins are generally aligned with a first group of chips on a first power card, and the second group of fins are generally aligned with a second group of chips on a second power card.

15. The heat sink of claim 14, wherein the plurality of fins includes a third group of fins between the first group of fins and the second group of fins, and generally aligned with a third group of chips on a third power card located between the first power card and the second power card.

16. The heat sink of claim 15, wherein:
the first wall segment extends through fins that are generally aligned with the first power card but not generally aligned with the first group of chips, and
the second wall segment extends through fins that are generally aligned with the third power card but not generally aligned with the third group of chips.

17. A heat sink for cooling power cards, the heat sink comprising:
an inlet region;
an outlet region;
a base having a lower surface and an opposing upper surface;
a plurality of fins spanning from the inlet region to the outlet region and extending from the upper surface for drawing heat from power cards located on the lower surface of the base, wherein the plurality of fins includes a first group of fins located near the inlet region and a second group of fins located near the outlet region, and wherein each of the plurality of fins includes a lower end at the upper surface of the base and an opposing upper end spaced from the base; and
a bypass wall vertically spaced from the upper surface of the base and configured to divert fluid from the inlet region to the second group of fins while bypassing at least some of the first group of fins, wherein the bypass wall extends along the upper ends of at least some of the first group of fins.

18. The heat sink of claim 17, wherein the bypass wall is a plate formed integrally with the upper ends of the first group of fins.

19. The heat sink of claim 17, wherein the fins within the first group of fins are shorter than the fins within the second group of fins.

20. The heat sink of claim 17, wherein the bypass wall is generally parallel to the upper surface of the base, and wherein a distance between the upper surface of the base and the bypass wall is less than a distance between the upper surface of the base and the upper ends of the fins within the second group of fins.
